(19) United States
(12) Patent Application Publication
(10) Pub. No.: US 2006/0006449 A1
(43) Pub. Date: Jan. 12, 2006

(54) Semiconductor integrated circuit devices having a hybrid dielectric layer and methods of fabricating the same

(76) Inventors: Yong-Kuk Jeong, Seoul (KR); Seok-Jun Won, Seoul (KR); Dae-Jin Kwon, Seoul (KR); Min-Woo Song, Seongnam-si (KR); Weon-Hong Kim, Suwon-si (KR)

Correspondence Address: MILLS & ONELLO LLP, ELEVEN BEACON STREET, SUITE 605, BOSTON, MA, 02108, US

(21) Appl. No.: 11/174,954

(22) Filed: Jul. 5, 2005

(30) Foreign Application Priority Data
Jul. 6, 2004 (KR) 10-2004-0052414

(51) Int. Cl. H01L 27/108

(52) U.S. Cl. 257/310; 257/295; 257/532

(57) ABSTRACT

In semiconductor integrated circuit devices having a hybrid dielectric layer and methods of fabricating the same, the hybrid dielectric layer includes a lower dielectric layer, an intermediate dielectric layer and an upper dielectric layer which are sequentially stacked. The lower dielectric layer contains hafnium (Hf) or zirconium (Zr). The upper dielectric layer also contains Hf or Zr. The intermediate dielectric layer is formed of a material layer having a voltage dependent capacitance variation lower than that of the lower dielectric layer.

### CROSS-REFERENCE TO RELATED APPLICATION

This application claims the benefit of Korean Patent Application No. 2004-52414, filed Jul. 6, 2004, the contents of which are hereby incorporated herein by reference in their entirety.

### BACKGROUND OF THE INVENTION

1. Field of the Invention

The present invention relates to semiconductor integrated circuit devices and methods of fabricating the same and, more particularly, to semiconductor integrated circuit devices having a hybrid dielectric layer and methods of fabricating the same;

2. Description of the Related Art

Semiconductor integrated circuit devices commonly include metal oxide semiconductor (MOS) transistors, resistors and capacitors. Capacitors are composed of upper and lower electrodes which overlap each other, and a dielectric layer interposed therebetween. The electrodes can be formed of a doped polysilicon layer. However, the polysilicon layer may be additionally oxidized during a subsequent heat treatment process, thereby degrading electrical characteristics of the capacitor. In addition, the capacitor may exhibit a non-uniform capacitance according to a magnitude of the voltage that is applied to the polysilicon electrodes. For example, when the upper and lower electrodes are formed of a polysilicon layer doped with N-type impurities and a negative voltage is applied to the upper electrode, holes are induced at a surface of the lower electrode. Accordingly, a depletion layer may be formed at the surface of the lower electrode. The width of the depletion layer is changed depending on the magnitude of the negative voltage, which is applied to the upper electrode. As a result, the capacitance of the capacitor may be changed depending on the magnitude of the voltage applied to the electrodes. Thus, capacitors employing polysilicon electrodes are not suitable for semiconductor integrated circuit devices that require the accurate capacitor characteristics, for example, semiconductor integrated circuit devices including analog circuits.

Furthermore, in order to increase the integration density of the semiconductor integrated circuit devices, it is desirable to form the dielectric layer of the capacitor using a material having a high dielectric constant. However, a high-k dielectric layer exhibits a large leakage current as compared to a low-k dielectric layer such as a silicon oxide layer.

Methods of fabricating a capacitor employing a high-k dielectric layer are disclosed in U.S. Pat. No. 6,071,771 to Schuegraf, entitled “Semiconductor processing method of forming a capacitor and capacitor constructions”. According to Schuegraf, a densified Ta₂O₅ layer is employed as a high-k dielectric layer exhibiting a small leakage current, and a nitride layer is interposed between the Ta₂O₅ layer and an electrode to suppress an oxidation reaction at an interface therebetween.

In addition, methods of improving the leakage current characteristics of a high-k dielectric layer are disclosed in U.S. Pat. No. 6,660,660 B2 to Haukka et al., entitled “Methods for making a dielectric stack in an integrated circuit”. According to Haukka et al, an aluminum oxide (Al₂O₃) layer or a lanthanum oxide (LaO) layer is provided as an interface layer between the high-k dielectric layer and the electrodes. These interface layers operate as an oxidation barrier layer and a diffusion barrier layer.

### SUMMARY OF THE INVENTION

One embodiment of the present invention provides semiconductor integrated circuit devices having a hybrid dielectric layer suitable for improving capacitance uniformity in response to applied voltage and for improving leakage current characteristics.

Another embodiment of the present invention provides methods of fabricating semiconductor integrated circuit devices having a hybrid dielectric layer suitable for improving capacitance uniformity in response to applied voltage and for improving leakage current characteristics.

In one aspect, the present invention is directed to semiconductor integrated circuit devices having a hybrid dielectric layer. The hybrid dielectric layer of the semiconductor integrated circuit devices includes a lower dielectric layer, an intermediate dielectric layer and an upper dielectric layer, which are sequentially stacked. The lower dielectric layer is a material layer containing hafnium (Hf) or zirconium (Zr), and the intermediate dielectric layer is a material layer having a voltage dependent capacitance variation lower than that of the lower dielectric layer. In addition, the upper dielectric layer contains hafnium (Hf) or zirconium (Zr).

In some embodiments, the lower dielectric layer may be one of a hafnium oxide (HfO) layer, a zirconium oxide (ZrO) layer and a hafnium-zirconium oxide (HfZrO) layer. In addition, the lower dielectric layer may be a combination layer of the HfO layer and the ZrO layer. For example, the lower dielectric layer may have a laminate structure in which the HfO layer and the ZrO layer are alternately and repeatedly stacked.

In other embodiments, the intermediate dielectric layer may be at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer and a Ti-doped TaO layer.

In yet other embodiments, the upper dielectric layer may be one of a hafnium oxide (HfO) layer, a zirconium oxide (ZrO) layer and a hafnium-zirconium oxide (HfZrO) layer. In addition, the upper dielectric layer may be a combination layer of the HfO layer and the ZrO layer. For example, the upper dielectric layer may have a laminate structure in which the HfO layer and the ZrO layer are alternately and repeatedly stacked.

In another aspect, the present invention is directed to methods of fabricating a semiconductor integrated circuit device having a hybrid dielectric layer. These methods include forming a lower dielectric layer containing hafnium (Hf) or zirconium (Zr) on an integrated circuit substrate. An intermediate dielectric layer is formed on the lower dielectric layer. The intermediate dielectric layer is formed of a material layer having a voltage dependent capacitance variation lower than that of the lower dielectric layer. An upper dielectric layer containing Hf or Zr is formed on the intermediate dielectric layer.

In some embodiments, the lower dielectric layer may be formed of one of a hafnium oxide (HfO) layer, a zirconium oxide (ZrO) layer and a hafnium-zirconium oxide (HfZrO) layer. In addition, the lower dielectric layer may be formed of a combination layer of the HfO layer and the ZrO layer. For example, the lower dielectric layer may be formed of a laminate layer in which the HfO layer and the ZrO layer are alternately and repeatedly stacked. The lower dielectric layer may be formed using an atomic layer deposition (ALD) technique or a chemical vapor deposition (CVD) technique.

In other embodiments, the intermediate dielectric layer may be formed of at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer and a Ti-doped TaO layer. The intermediate dielectric layer may be formed using an ALD technique or a CVD technique.

In yet other embodiments, the upper dielectric layer may be formed of one of a hafnium oxide (HfO) layer, a zirconium oxide (ZrO) layer and a hafnium-zirconium oxide (HfZrO) layer. In addition, the upper dielectric layer may be formed of a combination layer of the HfO layer and the ZrO layer. For example, the upper dielectric layer may be formed of a laminate layer in which the HfO layer and the ZrO layer are alternately and repeatedly stacked. The upper dielectric layer may be formed using an ALD technique or a CVD technique.

In another aspect, the present invention is directed to a capacitor comprising: a lower electrode on an integrated circuit substrate; a lower dielectric layer pattern on the lower electrode, the lower dielectric layer containing hafnium (Hf) or zirconium (Zr); an intermediate dielectric layer pattern on the lower dielectric layer pattern, a voltage dependent capacitance variation of the intermediate dielectric layer being lower than that of the lower dielectric layer pattern; an upper dielectric layer pattern on the intermediate dielectric layer pattern, the upper dielectric layer containing hafnium (Hf) or zirconium (Zr); and an upper electrode on the upper dielectric layer pattern.

In one embodiment, the lower electrode and the upper electrode are a metal layer.

In another aspect, the present invention is directed to a method of fabricating a capacitor, comprising: forming a lower electrode layer on an integrated circuit substrate; forming a lower dielectric layer on the lower electrode, the lower dielectric layer containing any one of hafnium (Hf) and zirconium (Zr); forming an intermediate dielectric layer on the lower dielectric layer, the intermediate dielectric layer being formed of a material layer having a voltage dependent capacitance variation lower than that of the lower dielectric layer; forming an upper dielectric layer on the intermediate dielectric layer, the upper dielectric layer containing any one of Hf and Zr; forming an upper electrode layer on the upper dielectric layer; and patterning the upper electrode layer, the upper dielectric layer, the intermediate dielectric layer, the lower dielectric layer and the lower electrode layer to form a lower electrode, a lower dielectric layer pattern, an intermediate dielectric layer pattern, an upper dielectric layer pattern and an upper electrode which are sequentially stacked.

In one embodiment, the lower electrode layer and the upper electrode layer are formed of a metal layer.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 and 2 are cross-sectional views illustrating methods of forming a capacitor in accordance with an embodiment of the present invention.

FIGS. 3 and 4 are cross-sectional views illustrating methods of forming a capacitor in accordance with another embodiment of the present invention.

FIG. 5 is a graph comparing leakage current characteristics of capacitors fabricated in accordance with the conventional approach and in accordance with an embodiment of the present invention.

FIG. 6 is a graph illustrating voltage dependent capacitance characteristics of capacitors fabricated in accordance with the conventional approach and in accordance with an embodiment of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete. In the drawings, the thickness of layers and regions are exaggerated for clarity. Like numbers refer to like elements throughout the specification.

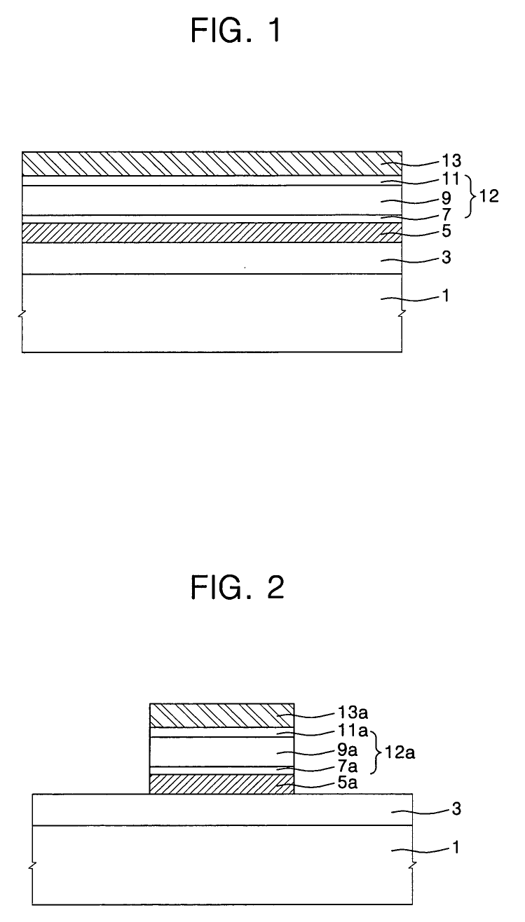

FIGS. 1 and 2 are cross-sectional views to illustrate methods of forming a capacitor in accordance with an embodiment of the present invention.

Referring to FIG. 1, an interlayer insulating layer 3 is formed on an integrated circuit substrate 1. A lower electrode layer 5, a lower dielectric layer 7, an intermediate dielectric layer 9, an upper dielectric layer 11 and an upper electrode layer 13 are sequentially formed on the interlayer insulating layer 3. The lower dielectric layer 7, the intermediate dielectric layer 9 and the upper dielectric layer 11 constitute a hybrid dielectric layer 12. The lower electrode layer 5 and the upper electrode layer 13 can be formed of metal layers. For example, each of the lower electrode layer 5 and the upper electrode layer 13 can be formed of at least one layer selected from the group consisting of a titanium (Ti) layer, a tantalum (Ta) layer, a titanium nitride (TiN) layer, a tantalum nitride (TaN) layer, a tungsten (W) layer, a tungsten nitride (WN) layer, an aluminum (Al) layer, a copper (Cu) layer, a ruthenium (Ru) layer, a ruthenium oxide (RuO) layer, a platinum (Pt) layer, an iridium (Ir) layer and an iridium oxide (IrO) layer. In addition, the lower electrode layer 5 and the upper electrode layer 13 may be formed, for example, using a physical vapor deposition technique, an atomic layer deposition (ALD) technique or a metal organic CVD technique.

The lower dielectric layer 7 and the upper dielectric layer 11 are formed of a material layer exhibiting a relatively lower leakage current than the intermediate dielectric layer 9. In other words, the lower dielectric layer 7 and the upper dielectric layer 11 are formed of a material layer having an energy band gap greater than that of the intermediate dielectric layer 9. For example, the lower dielectric layer 7 and the upper dielectric layer 11 may be formed of a material layer containing hafnium (Hf) or zirconium (Zr). In detail, the lower dielectric layer 7 and the upper dielectric layer 11 may be formed of one of a hafnium oxide (HfO) layer, a zirconium oxide (ZrO) layer and a hafnium-zirconium oxide (HfZrO) layer. Alternatively, the lower dielectric layer 7 may be formed of a combination layer of the HfO layer and the ZrO layer. For example, the lower dielectric layer 7 may be formed by alternately and repeatedly depositing the HfO layer and the ZrO layer. That is, the lower dielectric layer may be formed of a laminate layer of the HfO layer and the ZrO layer. The upper dielectric layer may also be formed of the laminate layer of the HfO layer and the ZrO layer. The lower dielectric layer 7 and the upper dielectric layer 11 may be formed using an atomic layer deposition (ALD) technique or a CVD technique at a low temperature of 25° C. to 500° C.

The intermediate dielectric layer 9 is formed of a material layer having a voltage-dependent capacitance variation less than those of the lower dielectric layer 7 and the upper dielectric layer 11. The voltage-dependent capacitance variation means a variation of a normalized capacitance of the dielectric layer when a voltage applied to the dielectric layer is increased or decreased. Accordingly, the intermediate dielectric layer 9 is preferably formed of a high-k dielectric layer having a capacitance that is constant regardless of the voltage. For example, the intermediate dielectric layer 9 may be formed of at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer and a Ti-doped TaO layer.

The intermediate dielectric layer 9 can optionally be formed using an atomic layer deposition technique or a CVD technique at a low temperature of 25° C. to 500° C. In addition, the intermediate dielectric layer 9 can be thermally treated using a gas containing oxygen, prior to formation of the upper dielectric layer 11. For example, the intermediate dielectric layer 9 may be thermally treated using an ozone gas, an oxygen plasma or an N₂O plasma at a low temperature of 100° C. to 500° C. The heat treatment process enhances the leakage current characteristics of the intermediate dielectric layer 9.

Referring to FIG. 2, the upper electrode layer 13, the hybrid dielectric layer 12 and the lower electrode layer 5 are patterned to form a lower electrode 5a, a lower dielectric layer pattern 7a, an intermediate dielectric layer pattern 9a, an upper dielectric layer pattern 11a and an upper electrode 13a which are sequentially stacked. The lower dielectric layer pattern 7a, the intermediate dielectric layer pattern 9a and the upper dielectric layer pattern 11a constitute a hybrid dielectric layer pattern 12a.

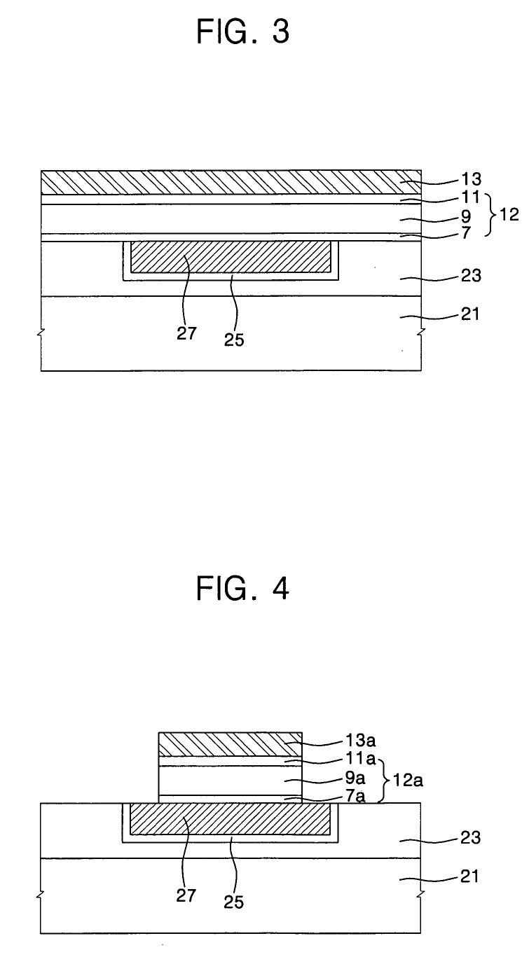

In the meantime, when the lower electrode layer 5 is formed of a metal layer such as a copper layer, it may be difficult to pattern the copper layer using conventional photolithography and etching processes. In this case, the lower electrode 5a may be formed using a damascene process as shown in FIGS. 3 and 4.

Referring to FIGS. 3 and 4, an interlayer insulating layer 23 is formed on an integrated circuit substrate 21. A predetermined region of the interlayer insulating layer 23 is partially etched to form a trench region. A lower electrode layer filling the trench region, for example a copper layer, is formed on the substrate having the trench region. A diffusion barrier layer may be formed prior to formation of the copper layer. The diffusion barrier layer may be formed of a metal nitride layer such as a TiN layer or a TaN layer. The lower electrode layer and the diffusion barrier layer are then planarized using a chemical mechanical polishing (CMP) technique to expose an upper surface of the interlayer insulating layer 23. As a result, a diffusion barrier layer pattern 25 covering an inner wall of the trench region, and a lower electrode 27 (i.e., a copper electrode) surrounded by the diffusion barrier layer pattern 25 are formed. The diffusion barrier layer pattern 25 prevents copper atoms in the copper electrode 27 from being diffused into the interlayer insulating layer 23.

Subsequently, the hybrid dielectric layer pattern 12a and the upper electrode 13a are formed on the copper electrode 27 using the same methods as described with reference to FIGS. 1 and 2.

### EXAMPLES

Hereinafter, the electrical characteristics of the hybrid dielectric layers fabricated according to the above-mentioned embodiments and the conventional art will be described.

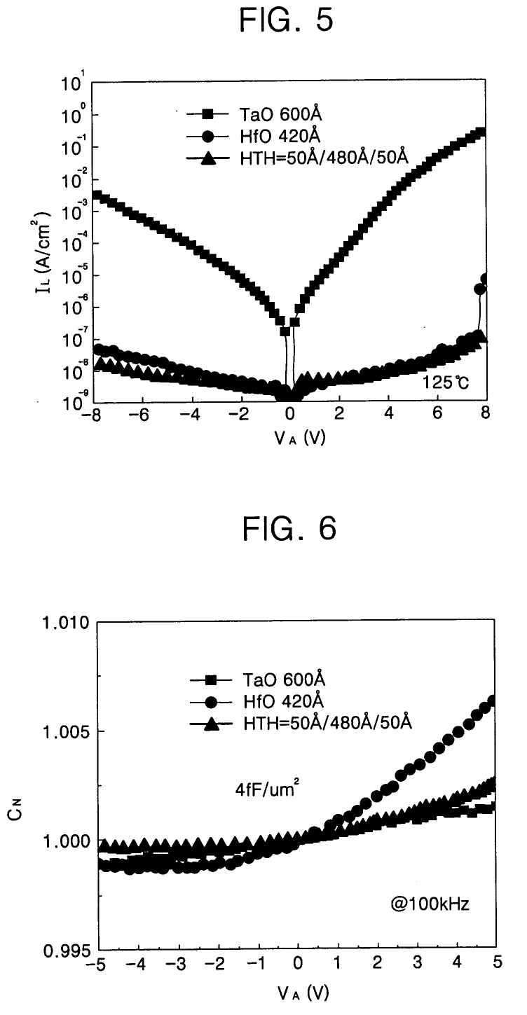

FIG. 5 is a graph that compares leakage current characteristics of capacitors fabricated in accordance with embodiments of the present invention and in accordance with the conventional art. In FIG. 5, the abscissa indicates a voltage V_{A} which is applied to upper electrodes of the capacitors, and the ordinate indicates a leakage current density I_{L} which flows through the dielectric layers. The leakage current density I_{L} was measured at a temperature of 125° C.

Capacitors exhibiting the measurement results of FIG. 5 were fabricated using the key process conditions described in the following Table 1.

TABLE 1

| | | Conventional | Conventional | Present |
|---|---|---|---|---|
| Process parameters | | art 1 | art 2 | invention |
| Lower electrode | | TiN layer (PVD) | | |
| Dielectric | Lower dielectric layer | TaO layer | HfO layer | HfO layer |
| Layer | | (600 Å, | (420 Å, ALD) | (50 Å, ALD) |
| | | MOCVD) | | |
| | Intermediate | | | TaO layer |
| | dielectric layer | | | (480 Å, MOCVD) |
| | Upper dielectric layer | | | HfO layer |
| | | | | (50 Å, ALD) |

| | |
|---|---|
| Upper electrode | TiN layer (PVD) |

As can be seen from table 1, all dielectric layers formed, whether in accordance with the conventional approach or in accordance with the present invention, were formed to have an equivalent oxide thickness of about 84 Å.

Referring to the table 1 and FIG. 5, when a voltage V_{A} of −8V or +8V was applied to a conventional capacitor employing a single tantalum oxide layer as a dielectric layer, the conventional capacitor exhibited a leakage current density I_{L} Of about 1×10⁻³ Ampere/cm² to 1×10⁻¹ Ampere/cm². On the contrary, another conventional capacitor employing a single hafnium oxide layer as a dielectric layer exhibited a low leakage current density I_{L} of about 1×10⁻⁷ Ampere/cm² at a voltage V_{A} of −8V or +8V. In addition, the capacitor employing a hybrid dielectric layer having a stacked structure of a hafnium oxide layer, a tantalum oxide layer and a hafnium oxide layer in accordance with the present invention also exhibited a low leakage current density I_{L} of about 1×10⁻⁷ Ampere/cm² at a voltage V_{A} of −8V or +8V. As a result, the single hafnium oxide layer or the hybrid dielectric layer containing the single hafnium oxide layer exhibited a significantly low leakage current density I_{L} as compared to the single tantalum oxide layer.

FIG. 6 is a graph comparing capacitance vs. voltage (CV) plots of capacitors fabricated according to embodiments of the present invention and capacitors fabricated according to the conventional art. In other words, FIG. 6 is a graph illustrating voltage-dependent capacitance variation characteristics. The capacitance was measured by applying a signal with a frequency of 100 kHz to the capacitors. In FIG. 6, the abscissa indicates a voltage V_{A} which is applied to upper electrodes of the capacitors, and the ordinate indicates a normalized capacitance (C_{N}) of the capacitors.

Capacitors exhibiting the measurement results of FIG. 6 were fabricated using the same process conditions as described in the table 1.

Referring to FIG. 6, when the voltage VA applied to a single hafnium oxide layer was increased from 0V to +8V, the normalized capacitance C_{N} was increased by about 0.0075. On the contrary, when the voltage V_{A} applied to a single tantalum oxide layer was increased from 0V to +8V, the normalized capacitance C_{N} was increased by about 0.0015. In addition, when a voltage applied to a hybrid dielectric layer having a stacked structure of a hafnium oxide layer, a tantalum oxide layer and a hafnium oxide layer was increased from 0V to +8V, the normalized capacitance (C_{N}) was increased by about 0.0025. As a result, the tantalum oxide layer or the hybrid dielectric layer containing the tantalum oxide layer exhibited a relatively low voltage dependent capacitance variation as compared to the single hafnium oxide layer.

In conclusion, as can be seen from FIGS. 5 and 6, the hybrid dielectric layer having a stacked structure of a hafnium oxide layer, a tantalum oxide layer and a hafnium oxide layer exhibited not only a low leakage current but also a low voltage-dependent capacitance variation.

According to the present invention as mentioned above, a hybrid dielectric layer of an intermediate dielectric layer having a relatively low voltage-dependent capacitance variation, and upper and lower dielectric layers having a relatively low leakage current is provided. Accordingly, a high performance capacitor exhibiting a low leakage current and a uniform capacitance may be implemented irrespective of the voltage variation applied to the capacitor employing the hybrid dielectric layer.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A semiconductor integrated circuit device having a hybrid dielectric layer, the hybrid dielectric layer comprising:
a lower dielectric layer containing hafnium (Hf) or zirconium (Zr);
an intermediate dielectric layer on the lower dielectric layer, a voltage dependent capacitance variation of the intermediate dielectric layer being lower than that of the lower dielectric layer; and
an upper dielectric layer on the intermediate dielectric layer, the upper dielectric layer containing hafnium (Hf) or zirconium (Zr).

2. The semiconductor integrated circuit device as recited in claim 1, wherein the lower dielectric layer is one of a hafnium oxide (HfO) layer, a zirconium oxide (ZrO) layer, a hafnium-zirconium oxide (HfZrO) layer, and a laminate layer of the HfO layer and the ZrO layer.

3. The semiconductor integrated circuit device as recited in claim 1, wherein the intermediate dielectric layer is at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer and a Ti-doped TaO layer

4. The semiconductor integrated circuit device as recited in claim 1, wherein the upper dielectric layer is one of an HfO layer, a ZrO layer, an HfZrO layer, and a laminate layer of the HfO layer and the ZrO layer.

5. A capacitor comprising:
a lower electrode on an integrated circuit substrate;
a lower dielectric layer pattern on the lower electrode, the lower dielectric layer containing hafnium (Hf) or zirconium (Zr);
an intermediate dielectric layer pattern on the lower dielectric layer pattern, a voltage dependent capacitance variation of the intermediate dielectric layer being lower than that of the lower dielectric layer pattern;
an upper dielectric layer pattern on the intermediate dielectric layer pattern, the upper dielectric layer containing hafnium (Hf) or zirconium (Zr); and
an upper electrode on the upper dielectric layer pattern.

6. The capacitor as recited in claim 5, wherein the lower electrode and the upper electrode are a metal layer.

7. The capacitor as recited in claim 6, wherein the metal layer is at least one layer selected from the group consisting of a titanium (Ti) layer, a tantalum (Ta) layer, a titanium nitride (TiN) layer, a tantalum nitride (TaN) layer, a tungsten (W) layer, a tungsten nitride (WN) layer, an aluminum (Al) layer, a copper (Cu) layer, a ruthenium (Ru) layer, a ruthenium oxide (RuO) layer, a platinum (Pt) layer, an iridium (Ir) layer and an iridium oxide (IrO) layer.

8. The capacitor as recited in claim 5, wherein the lower dielectric layer pattern is one of a hafnium oxide (HfO) layer, a zirconium oxide (ZrO) layer, a hafnium-zirconium oxide (HfZrO) layer, and a laminate layer of the HfO layer and the ZrO layer.

9. The capacitor as recited in claim 5, wherein the intermediate dielectric layer pattern is at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer, and a Ti-doped TaO layer.

10. The capacitor as recited in claim 5, wherein the upper dielectric layer pattern is one of a hafnium oxide (HfO) layer, a zirconium oxide (ZrO) layer, a hafnium-zirconium oxide (HfZrO) layer, and a laminate layer of the HfO layer and the ZrO layer.

11. A method of fabricating a semiconductor integrated circuit device, comprising:
forming a lower dielectric layer containing hafnium (Hf) or zirconium (Zr) on an integrated circuit substrate;
forming an intermediate dielectric layer on the lower dielectric layer, the intermediate dielectric layer being formed of a material layer having a voltage dependent capacitance variation lower than that of the lower dielectric layer; and
forming an upper dielectric layer containing hafnium (Hf) or zirconium (Zr) on the intermediate dielectric layer.

12. The method as recited in claim 11, wherein the lower dielectric layer is formed of one of a hafnium oxide (HfO) layer, a zirconium oxide (ZrO) layer, a hafnium-zirconium oxide (HfZrO) layer, and a laminate layer of the HfO layer and the ZrO layer.

13. The method as recited in claim 12, wherein the lower dielectric layer is formed using an atomic layer deposition (ALD) technique or a chemical vapor deposition (CVD) technique.

14. The method as recited in claim 11, wherein the intermediate dielectric layer is formed of at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer, and a Ti-doped TaO layer

15. The method as recited in claim 14, wherein the intermediate dielectric layer is formed using an ALD technique or a CVD technique.

16. The method as recited in claim 11, wherein the upper dielectric layer is formed of one of a hafnium oxide (HfO) layer, a zirconium oxide (ZrO) layer, a hafnium-zirconium oxide (HfZrO) layer, and a laminate layer of the HfO layer and the ZrO layer.

17. The method as recited in claim 16, wherein the upper dielectric layer is formed using an ALD technique or a CVD technique.

18. A method of fabricating a capacitor, comprising:
forming a lower electrode layer on an integrated circuit substrate;
forming a lower dielectric layer on the lower electrode, the lower dielectric layer containing any one of hafnium (Hf) and zirconium (Zr);
forming an intermediate dielectric layer on the lower dielectric layer, the intermediate dielectric layer being formed of a material layer having a voltage dependent capacitance variation lower than that of the lower dielectric layer;
forming an upper dielectric layer on the intermediate dielectric layer, the upper dielectric layer containing any one of Hf and Zr;
forming an upper electrode layer on the upper dielectric layer; and
patterning the upper electrode layer, the upper dielectric layer, the intermediate dielectric layer, the lower dielectric layer and the lower electrode layer to form a lower electrode, a lower dielectric layer pattern, an intermediate dielectric layer pattern, an upper dielectric layer pattern and an upper electrode which are sequentially stacked.

19. The method as recited in claim 18, wherein the lower electrode layer and the upper electrode layer are formed of a metal layer.

20. The method as recited in claim 19, wherein the metal layer is formed of at least one layer selected from the group consisting of a titanium (Ti) layer, a tantalum (Ta) layer, a titanium nitride (TiN) layer, a tantalum nitride (TaN) layer, a tungsten (W) layer, a tungsten nitride (WN) layer, an aluminum (Al) layer, a copper (Cu) layer, a ruthenium (Ru) layer, a ruthenium oxide (RuO) layer, a platinum (Pt) layer, an iridium (Ir) layer and an iridium oxide (IrO) layer.

21. The method as recited in claim 18, wherein the lower dielectric layer is formed of one of a hafnium oxide (HfO) layer, a zirconium oxide (ZrO) layer, a hafnium-zirconium oxide (HfZrO) layer, and a laminate layer of the HfO layer and the ZrO layer.

22. The method as recited in claim 21, wherein the lower dielectric layer is formed using an atomic layer deposition (ALD) technique or a chemical vapor deposition (CVD) technique.

23. The method as recited in claim 18, wherein the intermediate dielectric layer is formed of at least one layer selected from the group consisting of a tantalum oxide layer, a titanium oxide layer, a BST (Ba,Sr,TiO₃) layer, a STO (Sr, TiO₃) layer, a PZT (Pb,Zr,TiO₃) layer, a TaON layer, a Nb-doped TaO layer and a Ti-doped TaO layer.

24. The method as recited in claim 23, wherein the intermediate dielectric layer is formed using an ALD technique or a CVD technique.

25. The method as recited in claim 18, wherein the upper dielectric layer is formed of one of a hafnium oxide (HfO) layer, a zirconium oxide (ZrO) layer, a hafnium-zirconium oxide (HfZrO) layer, and a laminate layer of the HfO layer and the ZrO layer.

26. The method as recited in claim 25, wherein the upper dielectric layer is formed using an ALD technique or a CVD technique.
